(19) United States
(12) Patent Application Publication
(10) Pub. No.: US 2019/0198708 A1
(43) Pub. Date: Jun. 27, 2019

(54) LIGHT EMITTING DIODE EPITAXIAL WAFER AND METHOD FOR MANUFACTURING THE SAME

(71) Applicant: ADVANCED OPTOELECTRONIC TECHNOLOGY, INC., Hsinchu Hsien 303 (TW)

(72) Inventors: CHING-HSUEH CHIU, Hukou (TW); PO-MIN TU, Hukou (TW); YA-WEN LIN, Hukou (TW)

(21) Appl. No.: 15/940,911

(22) Filed: Mar. 29, 2018

(30) Foreign Application Priority Data
Dec. 22, 2017 (CN) 201711401679.5

(51) Int. Cl. H01L 33/06; H01L 33/14; H01L 33/32; H01L 33/00

(52) U.S. Cl. CPC H01L 33/06; H01L 33/145; B82Y 20/00; H01L 33/0066; H01L 33/325

(57) ABSTRACT

An epitaxial wafer as a light emitting diode (LED) comprises a sapphire substrate, a buffer layer, an N-type semiconductor layer, a light emitting active layer, and a P type semiconductor layer. The buffer layer, the N-type semiconductor layer, the light emitting active layer, and the P type semiconductor layer are formed on C-plane of the sapphire substrate in that order. The light-emitting active layer comprises at least one quantum well structure, with a quantum well region, a gradient region, a high-content aluminum region, and a blocking region. The blocking region covers and is connected to the high-content aluminum region, the P-type semiconductor layer of aluminum-doped or indium-doped gallium nitride covers the gradient region. Content of aluminum or indium changes linearly from side close to the N-type semiconductor layer to side furthest from the N-type semiconductor layer.

### FIELD

The subject matter relates to a light emitting device, and particularly relates to a light emitting diode (LED) epitaxial wafer and a method for manufacturing the same.

### BACKGROUND

During the manufacturing of LEDs, InGaN/GaN films are grown on the C-plane of a sapphire substrate. However, Quantum Confined Stark Effect (QCSE) may be generated in the LEDs, which reduces the internal quantum efficiency and the luminosity intensity. Improvements in the art are preferred.

### BRIEF DESCRIPTION OF THE DRAWINGS

Implementations of the present disclosure will now be described, by way of example only, with reference to the attached figures, wherein:

FIG. 1 is a cross-sectional view of an exemplary embodiment of an LED epitaxial wafer, in accordance with the present disclosure.

FIG. 2 is a diagram showing a content of aluminum linearly increasing in a quantum well region of the LED epitaxial wafer of FIG. 1, in accordance with a first exemplary embodiment of the present disclosure.

FIG. 3 is a diagram showing a content of indium linearly increasing in a quantum well region of the LED epitaxial wafer of FIG. 1, in accordance with a second exemplary embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details.

In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

Definitions that apply throughout this disclosure will now be presented.

The term “substantially” is defined to be essentially conforming to the particular dimension, shape, or other feature that the term modifies, such that the component need not be exact. For example, “substantially rectangular” means that the object resembles a rectangle, but can have one or more deviations from a true rectangle.

The term “comprising,” when utilized, means “including, but not necessarily limited to”; it specifically indicates open-ended inclusion or membership in the so-described combination, assembly, series, and the like.

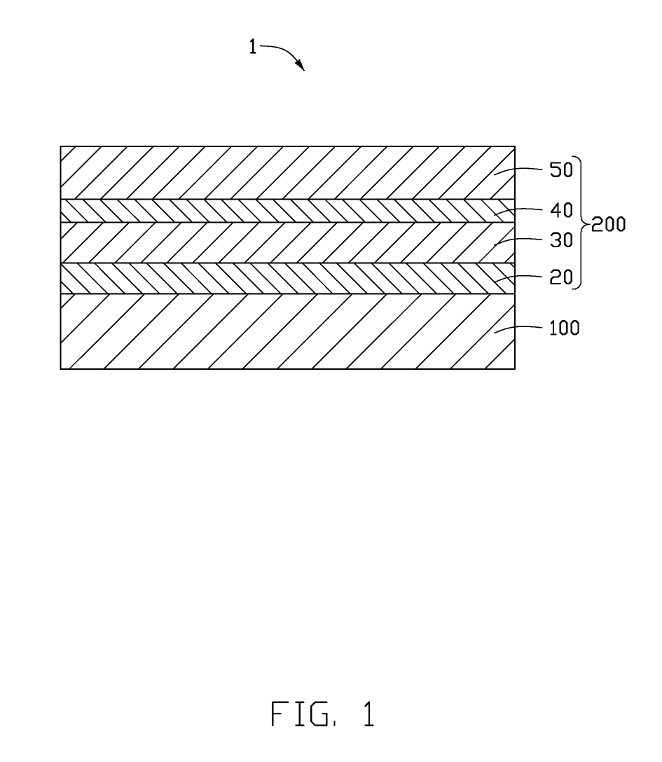

Referring to FIG. 1, the LED epitaxial wafer 1 comprises a substrate 100 and an epitaxial structure 200. The epitaxial structure 200 is grown on the substrate 100.

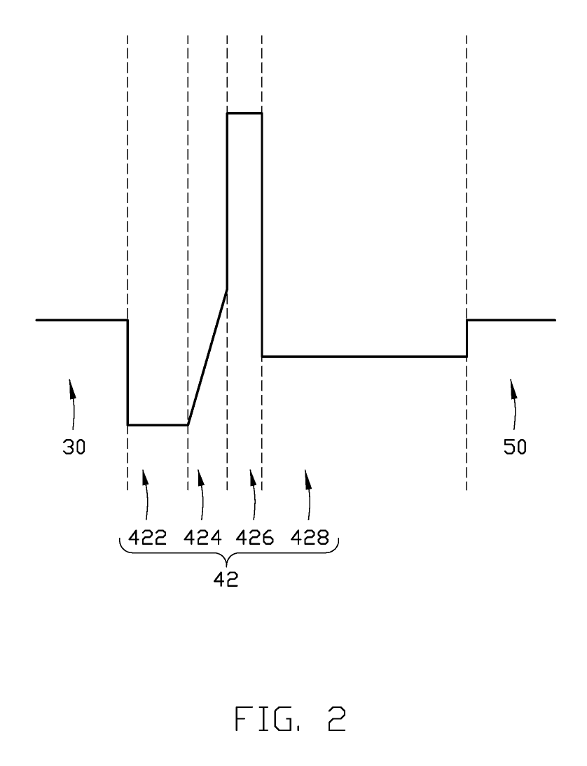

Referring to FIG. 2, the substrate 100 is made of sapphire that has a high mechanical strength and is easy to be processed. The epitaxial structure 200 is formed on the C-plane of the substrate 100.

The epitaxial structure 200 comprises a buffer layer 20, an N-type semiconductor layer 30, a light-emitting active layer 40, and a P-type semiconductor layer 50. The buffer layer 20, the N-type semiconductor layer 30, the light-emitting active layer 40, and the P-type semiconductor layer 50 are formed on the c-plane of the substrate 100 in that order. The buffer layer 20 is made of pure gallium nitride (GaN), which is mainly used to reduce lattice defects of the N-type semiconductor layer 30. An ohmic contact layer (not shown) may be disposed on the P-type semiconductor layer 50, in order to improve current transmission efficiency.

The P-type semiconductor layer 50 provides electron holes, and is mainly made of P-type gallium nitride (GaN). The N-type semiconductor layer 30 provides electrons, and is mainly made of doped gallium nitride (GaN), such as AlGaN. The light-emitting active layer 40 is made of gallium nitride-based material, such as InGaN, GaN, and generates light. The light-emitting active layer 40 further limits electrons and holes to increase the luminous intensity.

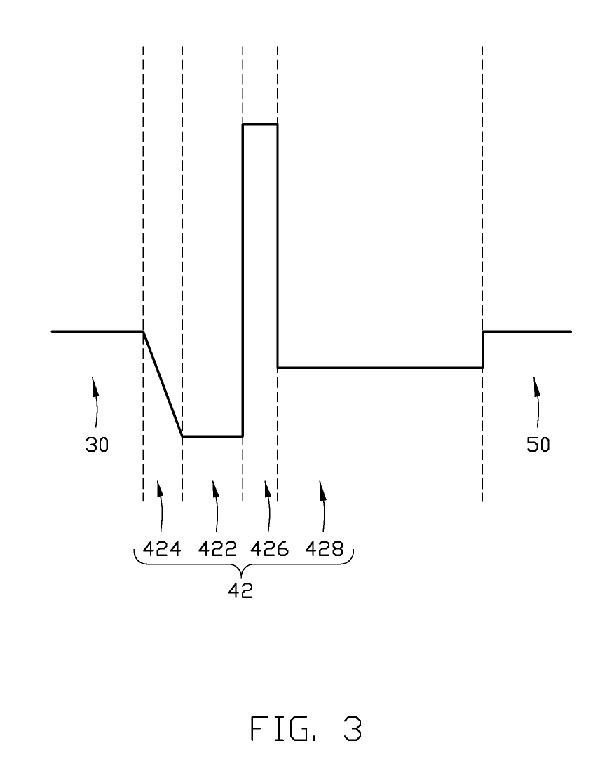

Referring to FIG. 2 and FIG. 3, the light-emitting active layer 40 comprises at least one quantum well structure 42. Each quantum well structure 42 comprises a quantum well region 422, a gradient region 424, a high-content aluminum region 426, and a blocking region 428. The blocking region 428 covers and connects with the high aluminum region 426. The P-type semiconductor layer 50 covers and connects with the blocking region 428. In the exemplary embodiment, the number of quantum well structures 42 is between 5 and 10.

### Example 1

Referring to FIG. 2, the quantum well region 422 covers and connects with the N-type semiconductor layer 30. The gradient region 424 is located between the quantum well region 422 and the high-content aluminum region 426, and connects the quantum well region 422 and the high-content aluminum region 426.

The quantum well region 422 is used to limit the electrons and electron holes to achieve effective recombination. The quantum well region 422 is made of indium-doped gallium nitride (GaN) that has a chemical formula of InₓGa₁₋ₓN, 0<x<1. The thickness of the quantum well region 422 ranges from 1 to 3 nanometers.

The gradient region 424 is used to reduce the quantum confinement Stark effect in the light-emitting diode. The gradient region 424 is made of aluminum-doped gallium nitride (GaN) that has a chemical formula of Al_{y}Ga_{1-y}N, 0<y≤1. The content of aluminum increases linearly from a side close to the N-type semiconductor layer 30 to the other side away from the N-type semiconductor layer 30. The thickness of the gradient region 424 ranges from 1 to 2 nanometers.

The high-content aluminum region 426 is used to block the diffusion of indium from the quantum well region 422 to the blocking region 428. The high-content aluminum region 426 is made of aluminum-doped gallium nitride (GaN) that has chemical formula of Al_{z}Ga_{1-z}N and 0.7≤z<1. The thickness of the high aluminum region 426 ranges from 1 to 2 nanometers.

The blocking region 428 is an electron blocking layer, and is made of indium-doped gallium nitride (GaN) that has a chemical formula of InₜGa₁₋ₜN, 0≤t<1. The blocking region 428 has a thickness of 10 to 12 nanometers.

A method for manufacturing the LED epitaxial wafer 1 of the example 1 comprises the following steps:

Step 1: a substrate 100 is provided.

Step 2: a buffer layer 20 is grown on the C-plane of the substrate 100. The buffer layer 20 can be formed by one of an organic metal chemical vapor deposition method, a radio frequency magnetron sputtering method, a chemical vapor deposition method, a physical vapor deposition method, an atomic layer deposition method, and a molecular beam deposition method.

Step 3: an N-type semiconductor layer 30 is grown on the buffer layer 20. The growth N-type semiconductor layer 30 may also be formed by one of organic metal chemical vapor deposition, radio frequency magnetron sputtering, chemical vapor deposition, physical vapor deposition, atomic layer deposition, and molecular beam deposition method.

Step 4: a quantum well region 422 is grown on the N-type semiconductor layer 30. The quantum well region 422 is made of indium-doped gallium nitride (GaN) that has a chemical formula of InₓGa₁₋ₓN, 0<x<1. The thickness of the quantum well region 422 ranges from 1 to 3 nanometers.

Step 5: a gradient region 424 is grown on the quantum well region 422. The aluminum gradient region is made of aluminum-doped gallium nitride (GaN) that has a chemical formula of Al_{y}Ga_{1-y}N, 0<y≤1. The content of aluminum increases linearly from a side close to the N-type semiconductor layer 30 to the other side away from the N-type semiconductor layer 30. The thickness of the aluminum gradient region ranges from 1 to 2 nanometers. The epitaxial temperature of the gradient region 424 is gradual and ranges from 50 to 100 degrees Celsius.

Step 6: a high aluminum region 426 is grown on the gradient region 422. The high-content aluminum region is made of aluminum-doped gallium nitride (GaN) that has a chemical formula of Al_{z}Ga_{1-z}N, and 0.7≤z<1. The thickness of the high aluminum region 426 ranges from 1 to 2 nanometers. The epitaxial temperature of the high-content aluminum region 426 is 50-100 degrees Celsius higher than that of the quantum well region 422.

Step 7: a blocking region 428 is grown on the high-content aluminum region 426. The blocking region 428 is made of indium-doped gallium nitride (GaN) that has a chemical formula of InₜGa₁₋ₜN, and 0≤t<1. The blocking region 428 has a thickness of 10 to 12 nanometers.

Step 8: a P-type semiconductor layer 50 is grown on the blocking region 4

Thus, the LED epitaxial wafer 1 is formed.

### Example 2

Referring to FIG. 3, the gradient region 424 covers and connects to the N-type semiconductor layer 30. The quantum well region 422 is located between the gradient region 424 and the high-content aluminum region 426, and connects the gradient region 424 and the high-content aluminum region 426.

The gradient region 424 is used to reduce the quantum confinement Stark effect in the light-emitting diode. The gradient region 424 is made of an indium-doped gallium nitride (GaN) that has chemical formula of InₓGa₁₋ₓN, 0≤x≤1. The content of indium decreases linearly from a side close to the N-type semiconductor layer 30 to the other side away from the N-type semiconductor layer 30. The thickness of the gradient region 424 ranges from 1 to 2 nanometers.

The quantum well region 422 is used to limit the electrons and electron holes to achieve effective recombination. The quantum well region 422 is made of indium-doped gallium nitride (GaN) that has a chemical formula of In_{y}Ga_{1-y}N, 0<y≤1. The thickness of the quantum well region 422 ranges from 1 to 3 nanometers.

The high-content aluminum region 426 is used to block the diffusion of indium from the quantum well region 422 to the blocking region 428. The high-content aluminum region is made of aluminum-doped gallium nitride (GaN) that has a chemical formula of Al_{z}Ga_{1-z}N and 0.7≤z<1. The thickness of the high aluminum region 426 ranges from 1 to 2 nanometers.

The blocking region 428 is an electron blocking layer, and is made of indium-doped gallium nitride (GaN) that has a chemical formula of InₜGa₁₋ₜN, 0≤t<1. The blocking region 428 has a thickness of 10 to 12 nanometers.

A method for manufacturing the LED epitaxial wafer 1 of the above example 2 comprises the following steps:

Step 1: a substrate 100 is provided.

Step 2: the buffer layer 20 is grown on the C-plane of the substrate 100. The buffer layer 20 can be formed by any one of an organic metal chemical vapor deposition method, a radio frequency magnetron sputtering method, a chemical vapor deposition method, a physical vapor deposition method, an atomic layer deposition method, and a molecular beam deposition method.

Step 3: an N-type semiconductor layer 30 is grown on the buffer layer 20. The growth N-type semiconductor layer 30 may also be formed by one of organic metal chemical vapor deposition, radio frequency magnetron sputtering, chemical vapor deposition, physical vapor deposition, atomic layer deposition, and molecular beam deposition method.

Step 4: a gradient region 424 is grown on the N-type semiconductor layer 30. The gradient region 424 is made of an indium-doped gallium nitride (GaN) that has a chemical formula of InₓGa₁₋ₓN, 0≤x≤1. The content of indium decreases linearly from a side close to the N-type semiconductor layer 30 to the other side away from the N-type semiconductor layer 30. The thickness of the indium gradient region ranges from 1 to 2 nanometers.

Step 5: a quantum well region 422 is grown on the indium gradient region. The quantum well region 422 is made of indium-doped gallium nitride (GaN) that has a chemical formula of In_{y}Ga_{1-y}N, 0<y≤1. The thickness of the quantum well region 422 ranges from 1 to 3 nanometers.

Step 6: a high-content aluminum region 426 is grown on the quantum well region 422. The high-content aluminum region 426 is made of aluminum-doped gallium nitride (GaN) that has a chemical formula of Al_{z}Ga_{1-z}N, and 0.7≤z<1. The thickness of the high aluminum region 426 ranges from 1 to 2 nanometers. The epitaxial temperature of the high-content aluminum region 426 is 50-100 degrees Celsius higher than that of the quantum well region 422.

Step 7: a blocking region 428 is grown on the high-content aluminum region 426. The blocking region 428 is made of an indium-doped gallium nitride (GaN) material having a chemical formula of InₜGa₁₋ₜN and 0≤t<1. The blocking region 428 has a thickness of 10 to 12 nanometers.

Step 8: a P-type semiconductor layer 50 is grown on the blocking region 428. Thus, the LED epitaxial wafer 1 is formed.

With the above configuration, the gradient region 424 is grown on the C-plane of the sapphire substrate 100. The content of indium or of aluminum of the gradient region 424 changes linearly from the side close to the N-type semiconductor layer 30 to the side away from the N-type semiconductor layer 30, so as to reduce the quantum confinement Stark effect. In addition, the quantum well structure 42 has a high-content aluminum region 426 that can reduce the phenomenon of indium diffusion in the blocking region 428 and the quantum well region 422, thereby enhancing the epitaxial quality of the light-emitting active layer 40.

The embodiments shown and described above are only examples. Many other details are found in the art. Therefore, many such details are neither shown nor described. Even though numerous characteristics and advantages of the present disclosure have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A light emitting diode (LED) epitaxial wafer comprising:
a sapphire substrate;
a buffer layer;
an N-type semiconductor layer;
a light emitting active layer; and
a P-type semiconductor layer;
wherein, the buffer layer, the N-type semiconductor layer, the light emitting active layer, and the P type semiconductor layer are formed on C-plane of the sapphire substrate in that order, wherein the light-emitting active layer comprises at least one quantum well structure, each quantum well structure comprises a quantum well region, a gradient region, a high-content aluminum region, and a blocking region, the blocking region covers and is connected to the high-content aluminum region, the P-type semiconductor layer covers the gradient region and is made of aluminum-doped or indium-doped gallium nitride, a content of aluminum or indium changes linearly from one side close to the N-type semiconductor layer to one side away from the N-type semiconductor layer.

2. The LED epitaxial wafer of claim 1, wherein the gradient region is made of aluminum-doped gallium nitride that has a chemical formula of Al_{y}Ga_{1-y}N, 0<y≤1, the content of aluminum increases linearly from the side close to the N-type semiconductor layer to the side away from the N-type semiconductor layer, the quantum well region covers and connects to the N-type semiconductor layer, the gradient region is located between the quantum well region and the high-content aluminum region, and connects the quantum well region and the high-content aluminum region.

3. The LED epitaxial wafer of claim 2, wherein the quantum well region is made of indium-doped gallium nitride that has a chemical formula of InₓGa₁₋ₓN, 0<x<1, the high-content aluminum region is made of aluminum-doped gallium nitride that has a chemical formula of Al_{z}Ga_{1-z}N, 0.7≤z<1, the blocking region is made of indium-doped gallium nitride that has a chemical formula of InₜGa₁₋ₜN, 0≤t<1.

4. The LED epitaxial wafer of claim 3, wherein the quantum well region has a thickness in a range from 1 to 3 nanometers, the gradient region has a thickness in a range from 1 to 2 nanometers, the high aluminum region has a thickness in a range from 1 to 2 nanometers, and the blocking region has a thickness in a range from 10 to 12 nanometers.

5. The LED epitaxial wafer of claim 1, wherein the gradient region is made of indium-doped gallium nitride that has a chemical formula of InₓGa₁₋ₓN, 0<x<1, the content of indium decreases linearly from the side close to the N-type semiconductor layer to the side away from the N-type semiconductor layer, the gradient region covers and connects to the N-type semiconductor layer, the quantum well region is located between the gradient region and the high-content aluminum region, and connects the gradient region and the high-content aluminum region.

6. The LED epitaxial wafer of claim 5, wherein the quantum well region is made of indium-doped gallium nitride that has a chemical formula of In_{y}Ga_{1-y}N, 0<y≤1, the high-content aluminum region is made of aluminum-doped gallium nitride that has a chemical formula of Al_{z}Ga_{1-z}N, 0.7≤z<1, the blocking region is made of indium-doped gallium nitride that has a chemical formula of InₜGa₁₋ₜN, 0≤t<1.

7. The LED epitaxial wafer of claim 6, wherein the gradient region has a thickness in a range from 1 to 2 nanometers, the quantum well region has a thickness in a range from 1 to 3 nanometers, the high aluminum region has a thickness in a range from 1 to 2 nanometers, and the blocking region has a thickness in a range from 10 to 12 nanometers.

8. The LED epitaxial wafer of claim 7, wherein the quantum well structure numbers from 5 to 10.

9. A method for manufacturing a light emitting diode epitaxial wafer comprising:
providing a sapphire substrate;
forming a buffer layer and an N-type semiconductor layer on C-plane of the sapphire substrate in that order;
forming at least one quantum well structure on the N-type semiconductor layer, each quantum well structure comprising a quantum well region, a gradient region, a high-content aluminum region, and a blocking region, the blocking region covering and connecting to the high-content aluminum region, wherein the P-type semiconductor layer covers the gradient region and is made of aluminum-doped or indium-doped gallium nitride, a content of aluminum or indium changes linearly from one side close to the N-type semiconductor layer to one side away from the N-type semiconductor layer; and
forming a P-type semiconductor layer on the blocking region.

10. The method of claim 9, wherein the gradient region is made of aluminum-doped gallium nitride that has a chemical formula of Al_{y}Ga_{1-y}N, 0<y≤1, the content of aluminum increases linearly from the side close to the N-type semiconductor layer to the side away from the N-type semiconductor layer, the step of forming at least one quantum well structure on the N-type semiconductor layer comprises: forming the quantum well region on the N-type semiconductor layer, forming the gradient region on the quantum well region, forming the high-content aluminum region on the gradient region.

11. The method of claim 10, wherein the material of the quantum well region is indium-doped gallium nitride, the chemical formula is InₓGa₁₋ₓN, 0<x<1, the high-content aluminum region is made of the high-content aluminum region is aluminum-doped gallium nitride, the chemical formula is Al_{z}Ga_{1-z}N, 0.7≤z<1, the material of the blocking region is indium-doped gallium nitride, and the chemical formula is InₜGa₁₋ₜN, 0≤t<1.

12. The method of claim 10, wherein the quantum well region has a thickness in a range from 1 to 3 nanometers, the gradient region has a thickness in a range from 1 to 2 nanometers, the high aluminum region has a thickness in a range from 1 to 2 nanometers, and the blocking region has a thickness in a range from 10 to 12 nanometers.

13. The method of claim 10, wherein the epitaxial temperature of the gradient region is a gradient temperature ranging from 50 to 100° C., the epitaxial temperature of the high-content aluminum region is 50-100 degrees Celsius higher than that of the quantum well region.

14. The method of claim 9, wherein the gradient region is made of indium-doped gallium nitride with a chemical formula of InₓGa₁₋ₓN, 0<x<1, the content of indium is linear from the side close to the N-type semiconductor layer to another side away from the N-type semiconductor layer, the step of forming at least one quantum well structure on the N-type semiconductor layer comprises: forming the gradient region on the N-type semiconductor layer, forming the quantum well region on the gradient region; and forming the high-content aluminum region on the quantum well region.

15. The method of claim 14, wherein the quantum well region is made of indium-doped gallium nitride, the chemical formula is In_{y}Ga_{1-y}N, 0<y≤1, the high-content aluminum region is made of aluminum-doped gallium nitride, the chemical formula is Al_{z}Ga_{1-z}N, 0.7≤z<1, the blocking region is made of indium-doped gallium nitride, and the chemical formula is InₜGa₁₋ₜN, 0≤t<1.

16. The method of claim 14, wherein the gradient region has a thickness in a range from 1 to 2 nanometers, the quantum well region has a thickness in a range from 1 to 3 nanometers, the high aluminum region has a thickness a range from 1 to 2 nanometers, and the blocking region has a thickness a range from 10 to 12 nanometers.

17. The method of claim 14, wherein the epitaxial temperature of the high-content aluminum region is 50-100 degrees Celsius higher than that of the quantum well region.
